(19) United States
(12) Patent Application Publication
(10) Pub. No.: US 2025/0279777 A1
(43) Pub. Date: Sep. 4, 2025

(54) METHODS AND APPARATUS TO REGULATE TRANSISTOR SWITCHING

(71) Applicant: Texas Instruments Incorporated, Dallas, TX (US)

(72) Inventors: Cetin Kaya, McKinney, TX (US); FNU Nitish, Dallas, TX (US); Yang-Lin Chen, Taoyuan City (TW)

(21) Appl. No.: 18/755,312

(22) Filed: Jun. 26, 2024

Related U.S. Application Data
(60) Provisional application No. 63/559,475, filed on Feb. 29, 2024.

(51) Int. Cl. H03K 17/06

(52) U.S. Cl. CPC H03K 17/063

(57) ABSTRACT

An example apparatus includes: current source circuitry having a control terminal; charging circuitry having a first terminal and a second terminal; capacitor circuitry having a first terminal, a second terminal, a third terminal, and a fourth terminal, the first terminal of the capacitor circuitry coupled to the second terminal of the charging circuitry, the second terminal of the capacitor circuitry coupled to the third terminal of the charging circuitry; and comparator circuitry having a first terminal, a second terminal, and an output terminal, the first terminal of the comparator circuitry coupled to the third terminal of the capacitor circuitry, the second terminal of the comparator circuitry coupled to the fourth terminal of the capacitor circuitry, the output terminal of the comparator circuitry coupled to the control terminal of the current source circuitry.

### CROSS-REFERENCE TO RELATED APPLICATION

This patent application claims the benefit of and priority to U.S. Provisional Patent Application No. 63/559,475 filed Feb. 29, 2024, which is hereby incorporated herein by reference in its entirety.

### TECHNICAL FIELD

This description relates generally to switching and, more particularly, to methods and apparatus to regulate transistor switching.

### BACKGROUND

As electronics continue to advance, systems have become capable of safely operating at increasingly complex operating conditions, such as higher powers and higher speeds. In driver circuitry, increasingly complex circuitry implements advanced techniques for regulating a supply of power to a load. Such circuitry allows the driver circuitry to precisely control and regulate transistor switching despite complex operating conditions.

### SUMMARY

For methods and apparatus to regulate transistor switching, an example apparatus includes current source circuitry having a control terminal; charging circuitry having a first terminal and a second terminal; capacitor circuitry having a first terminal, a second terminal, a third terminal, and a fourth terminal, the first terminal of the capacitor circuitry coupled to the second terminal of the charging circuitry, the second terminal of the capacitor circuitry coupled to the third terminal of the charging circuitry; and comparator circuitry having a first terminal, a second terminal, and an output terminal, the first terminal of the comparator circuitry coupled to the third terminal of the capacitor circuitry, the second terminal of the comparator circuitry coupled to the fourth terminal of the capacitor circuitry, the output terminal of the comparator circuitry coupled to the control terminal of the current source circuitry. Other examples are described.

For methods and apparatus to regulate transistor switching, an example apparatus includes an capacitor circuitry including: a set of first capacitors; and a set of second capacitors; charging circuitry coupled to the capacitor circuitry, the charging circuitry configured to: generate a reference voltage by discharging the set of first capacitors; and generate a switching voltage by charging the set of second capacitors; and comparator circuitry coupled to the capacitor circuitry, the comparator circuitry configured to decrease a drive current responsive to a comparison of the reference voltage to the switching voltage. Other examples are described.

For methods and apparatus to regulate transistor switching, an example apparatus includes a transistor having a control terminal; and current source circuitry having a first terminal and a control terminal, the first terminal of the current source circuitry coupled to the control terminal of the transistor; comparator circuitry having a first terminal, a second terminal, and an output terminal, the output terminal of the comparator circuitry coupled to the control terminal of the current source circuitry; and capacitor circuitry having a first terminal and a second terminal, the first terminal of the capacitor circuitry coupled to the first terminal of the comparator circuitry, the second terminal of the capacitor circuitry coupled to the second terminal of the comparator circuitry. Other examples are described.

### BRIEF DESCRIPTION OF THE DRAWINGS

FIG. 1 is a block diagram of an example drive system including gate driver circuitry that uses example current multiplication circuitry and an auxiliary current source to adjust a drive current to reduce stress on a motor during switching.

FIG. 2 is a schematic diagram of the example drive system of FIG. 1.

FIG. 3 is a schematic diagram of a first configuration of the example drive system of FIGS. 1 and 2.

FIG. 4 is a schematic diagram of a second configuration of the example drive system of FIGS. 1, 2, and 3.

FIG. 5 is a schematic diagram of an example of the current multiplication circuitry of FIGS. 1, 2, 3, and 4.

FIG. 6 is a flowchart representative of example operations that may be at least one of executed, instantiated, or performed to implement the current multiplication circuitry of FIGS. 1, 2, 3, 4, and 5 to regulate a slew-rate of a voltage across a transistor.

FIG. 7 is a flowchart representative of example operations that may be at least one of executed, instantiated, or performed to implement the gate driver circuitry of FIGS. 1, 2, 3, and 4 to dynamically adjust a slew-rate of a voltage across a transistor.

FIG. 8 is a timing diagram of example operations of the gate driver circuitry of FIGS. 1, 2, 3, and 4 to regulate the slew-rate of a voltage across a transistor.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

As electronics continue to advance, systems have become capable of safely operating at increasingly complex operating conditions, such as higher powers and higher speeds. In driver circuitry, increasingly complex circuitry implements advanced techniques for regulating a supply of power to a load. Such circuitry allows the driver circuitry to precisely control and regulate transistor switching despite complex operating conditions.

When driving direct current (DC) motors, driver circuitry connected to one terminal of the DC motor regulates a supply of power to the motor by controlling transistors, while the remaining terminal of the DC motor is connected to ground. A first transistor (referred to as a high-side transistor) controls a supply of power from a supply terminal to the motor and a second transistor (referred to as a low-side transistor) controls a supply of power from the motor to a common potential. During operations to drive (e.g., supply power to, cause motion of) the motor, the driver circuitry switches the transistors on and off to regulate a supply of power to the motor. In a first operation, the driver circuitry turns on the first transistor (e.g., enables, causes to conduct current) and turns off the second transistor (e.g., disables, causes to not conduct current). In a second operation, the driver circuitry turns off the first transistor and turns on the second transistor.

Switching between the first and second operations of the transistors allows the driver circuitry to regulate the supply of power to the motor. In some systems, modifying the ratio of time in the first operation opposed to time in the second operation allows the driver circuitry to control operations of the motor, such as speed, torque, etc. In such systems, the driver circuitry receives one or more control signals that use pulse width modulation (PWM) to control the timing of switching between configurations. The one or more control signals control the timing of switching using duty cycles, which represents a ratio of time that the driver circuitry is turned on (e.g., supplying power) over the time that the driver circuitry is turned off (e.g., not supplying power). Increasing the duty cycle of a control signal increases the power delivered to the motor, which increases the speed or torque of the motor. Decreasing the duty cycle of the control signal decreases the power delivered to the motor, which decreases the speed or torque of the motor.

As transistor technologies continue to advance, the speeds at which transistors can switch continue to increase. As the switching speeds of transistors increase, the amount of time that a transistor takes to transition between being on and off decreases. Such transitions are characterized by a slew rate, which is a rate (e.g., volts per second) characterizing the change in voltage across the transistor. For example, when switching between a common potential (e.g., 0 volts, ground) and a four-hundred-volt supply, the slew rate characterizes the rate at which the drain-to-source voltage across a transistor either increases or decreases.

In some systems, driver circuitry sets the slew rate of the transistor by controlling a current at a gate terminal of the transistor (referred to as a gate drive current). The slew rate of the transistor increases as the gate drive current increases. However, in some systems, such as motor control, increasing the slew rate of the transistors increases the stress applied to components of the motor during switching. To regulate the gate drive current, which regulates the slew rate, some driver circuitry includes a capacitor (referred to as a high-voltage capacitor) having a relatively large capacitance between the gate and drain terminals of the transistor. To support the increasingly high voltage switching the capacitance of the capacitor continues to increase. The capacitor uses portions of the gate drive current to compensate for changes in the voltage of the transistor, which reduces the gate drive current. However, as switching voltages and currents continue to increase the capacitance of the capacitor continues to increase, which increases the system on chip (SoC) size of the driver circuitry.

Examples described herein include methods and apparatus to regulate transistor switching. In some described examples, gate driver circuitry generates and controls a gate drive current to regulate a slew rate of a voltage change across a transistor during a switching operation. The gate driver circuitry includes current multiplication circuitry that is coupled to the transistor by a relatively small capacitor. When switching begins, the gate driver circuitry supplies a first gate drive current to the gate of the transistor using first and second current source circuitry. Once the gate drive current enables the transistor (e.g., turns on, causes conduction), the capacitor begins to source current from the current multiplication circuitry responsive to a change in the voltage across the transistor. The current multiplication circuitry mirrors and scales the current being supplied to the capacitor. The current multiplication circuitry sinks the scaled current from the gate drive current, which mimics having a relatively large capacitance coupled between the gate and drain of the transistor. Advantageously, the current multiplication circuitry uses a capacitor having a relatively small capacitance to mimic having a relatively large capacitance coupled between the gate and drain of the transistor. Advantageously, the current multiplication circuitry prevents excessively high slew rates of the transistor from stressing a load by limiting the slew rate.

Also described herein, are examples where the gate driver circuitry includes first and second current source circuitry, charging circuitry, capacitor circuitry, and comparator circuitry. The first and second current source circuitry generate the gate drive current responsive to a control signal from external circuitry. The charging circuitry charges capacitors of the capacitor circuitry. In some examples, the capacitor circuitry includes a set of first capacitors and a set of second capacitors, which the charging circuitry is structured to charge. When charging, the set of capacitors generate a switching voltage. When not being charged, the set of capacitors supply a reference voltage. In example operations, the charging circuitry is structured to charge one of the set of capacitors and use the other one of the set of capacitors to supply the reference voltage. For example, the charging circuitry may charge the set of first capacitors to generate the switching voltage and use the set of second capacitors to supply the reference voltage. The comparator circuitry compares the switching voltage and the reference voltage. The comparator circuitry controls the second current source circuitry responsive to the comparison of the switching voltage to the reference voltage. In some examples, once the switching voltage becomes greater than the reference voltage, the comparator circuitry disables the second current source circuitry, which decreases the gate drive current and the slew rate of the transistor.

Advantageously, the gate driver circuitry described herein includes circuitry to adjust the slew rate of the transistor during switching operations. Advantageously, using a relatively high slew rate increases power efficiency and using a relatively low slew rate decreases stress on a load. Advantageously, the gate driver circuitry initially sets the transistor to have a relatively high slew rate before decreasing the gate drive current to reduce the slew rate. Advantageously, switching between different slew rates increases power efficiency without excessively stressing the load.

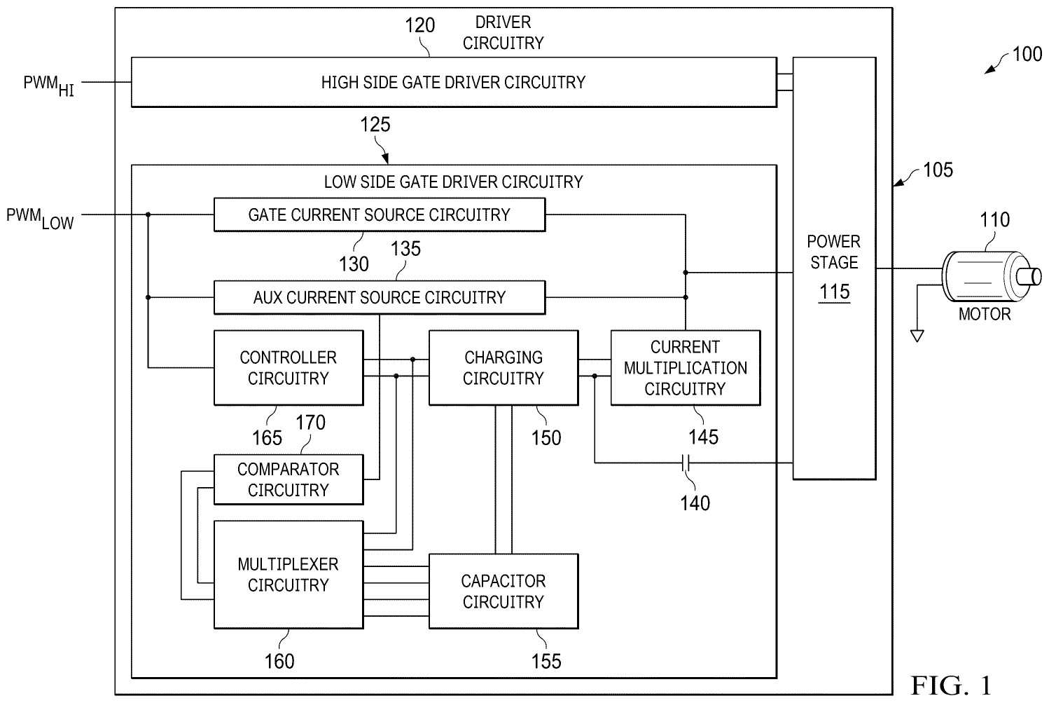

FIG. 1 is a block diagram of an example drive system 100. In the example of FIG. 1, the drive system 100 includes example driver circuitry 105 and an example motor 110. The driver circuitry 105 of FIG. 1 includes example power stage circuitry 115, example high-side gate driver circuitry 120, and example low-side gate driver circuitry 125. The low-side gate driver circuitry 125 of FIG. 1 includes first example current source circuitry 130, second example current source circuitry 135, an example capacitor 140, example current multiplication circuitry 145, example charging circuitry 150, example capacitor circuitry 155, example multiplexer circuitry 160, example controller circuitry 165, and example comparator circuitry 170.

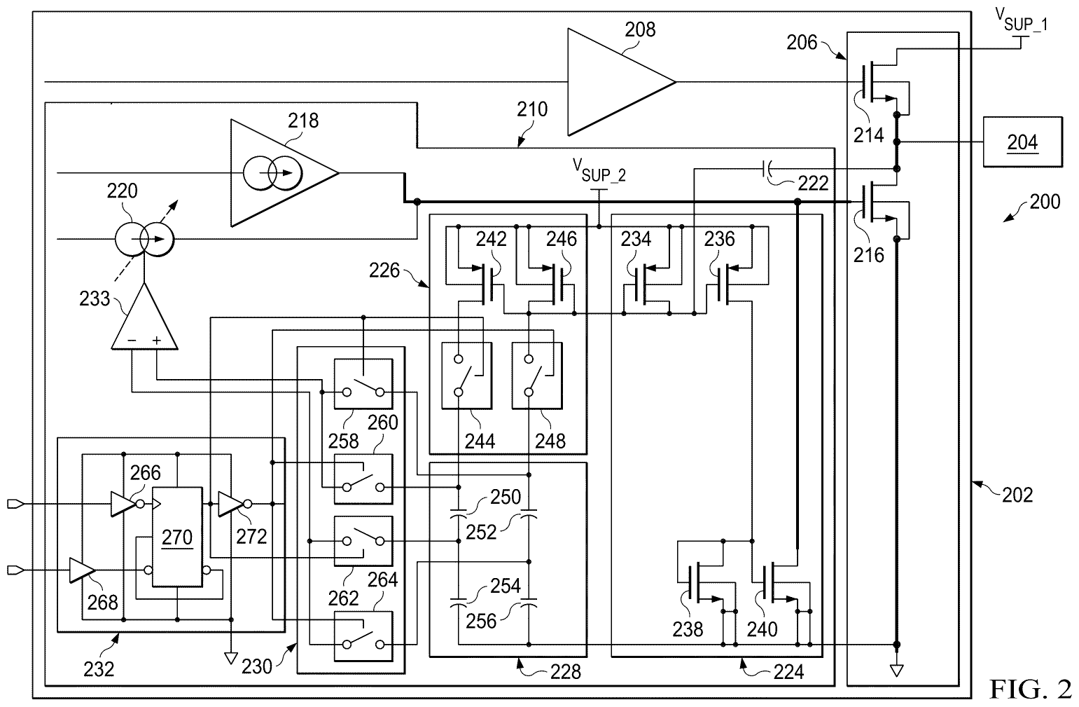

The driver circuitry 105 is coupled to the motor 110. In some examples, the driver circuitry 105 is coupled to an external signal source, such as programmable circuitry, which is structured to supply one or more control signals. Examples of the driver circuitry 105 are further illustrated and described in connection with FIGS. 2, 3, 4, and 5, below. Although in the example of FIG. 1, the driver circuitry 105 includes the gate driver circuitry 120, 125 and the power stage circuitry 115, in other examples, the power stage circuitry 115 may be external to the driver circuitry 105.

The motor 110 has a first terminal and a second terminal. The first terminal of the motor 110 is coupled to the driver circuitry 105. The second terminal of the motor 110 is coupled to a common terminal, which supplies a common potential (e.g., ground). In some examples, the motor 110 is physically coupled to an external system. For example, in automotive systems, the motor 110 is mechanically coupled to a wheel. In industrial systems, the motor 110 is mechanically coupled to one or more components to drive operations, such as manufacturing. In the example of FIG. 1, the motor 110 is a direct current (DC) motor. Alternatively, the drive system 100 of FIG. 1 may be modified to replace the motor 110 with a stepper motor or alternative type of motor. Although in the example of FIG. 1, the driver circuitry 105 is structured to supply power to the motor 110, the driver circuitry 105 may be coupled to any type of load.

The power stage circuitry 115 has a first terminal, a second terminal, a third terminal, a fourth terminal, and a fifth terminal. The first and second terminals of the power stage circuitry 115 are coupled to the gate driver circuitry 120. The third and fourth terminals of the power stage circuitry 115 are coupled to the gate driver circuitry 125. The fifth terminal of the power stage circuitry 115 is coupled to the motor 110. Examples of the power stage circuitry 115 are illustrated and described in connection with FIGS. 2, 3, 4, and 5, below.

The gate driver circuitry 120 has a first terminal, a second terminal, and a third terminal. The first and second terminals of the gate driver circuitry 120 are coupled to the power stage circuitry 115. The third terminal of the gate driver circuitry 120 may be coupled to external circuitry structured to supply a high-side control signal (PWM_{HI}). The low-side control signal is a PWM signal that controls the switching of the power stage circuitry 115.

The gate driver circuitry 125 has a first terminal, a second terminal, and a third terminal. The first and second terminals of the gate driver circuitry 125 are coupled to the power stage circuitry 115. The third terminal of the gate driver circuitry 125 may be coupled to external circuitry that is structured to supply a low-side control signal (PWM_{LOW}). The low-side control signal is a PWM signal that controls the switching of the power stage circuitry 115. Examples of the gate driver circuitry 125 are illustrated and described in connection with FIGS. 2, 3, 4, and 5, below.

The current source circuitry 130 has a first terminal and a second terminal. The first terminal of the current source circuitry 130 is coupled to the current source circuitry 135, the controller circuitry 165, and may be coupled to external circuitry that is structured to supply the low-side control signal. The second terminal of the current source circuitry 130 is coupled to the power stage circuitry 115, the current source circuitry 135, and the current multiplication circuitry 145. Examples of the current source circuitry 130 are illustrated and described in connection with FIGS. 2, 3, 4, and 5, below.

The current source circuitry 135 has a first terminal, a second terminal, and a control terminal. The first terminal of the current source circuitry 135 is coupled to the current source circuitry 130, the controller circuitry 165, and may be coupled to external circuitry that is structured to supply the low-side control signal. The second terminal of the current source circuitry 135 is coupled to the power stage circuitry 115, the current source circuitry 130, and the current multiplication circuitry 145. The control terminal of the current source circuitry 135 is coupled to the comparator circuitry 170. An example of the current source circuitry 135 is illustrated and described in connection with FIGS. 2, 3, and 4, below.

The capacitor 140 has a first terminal and a second terminal. The first terminal of the capacitor 140 is coupled to the power stage circuitry 115. The second terminal of the capacitor 140 is coupled to the current multiplication circuitry 145 and the charging circuitry 150. Examples of the capacitor 140 are illustrated and described in connection with FIGS. 2, 3, 4, and 5, below.

The current multiplication circuitry 145 has a first terminal, a second terminal, and a third terminal. The first terminal of the current multiplication circuitry 145 is coupled to the power stage circuitry 115 and the current source circuitry 130, 135. The second terminal of the current multiplication circuitry 145 is coupled to the charging circuitry 150. The third terminal of the current multiplication circuitry 145 is coupled to the capacitor 140 and the charging circuitry 150. Examples of the current multiplication circuitry 145 are illustrated and described in connection with FIGS. 2, 3, 4, and 5, below.

The charging circuitry 150 has a first terminal, a second terminal, a third terminal, a fourth terminal, a fifth terminal, and a sixth terminal. The first terminal of the charging circuitry is coupled to the capacitor 140 and the current multiplication circuitry 145. The second terminal of the charging circuitry 150 is coupled to the current multiplication circuitry 145. The third and fourth terminals of the charging circuitry 150 are coupled to the capacitor circuitry 155. The fifth and sixth terminals of the charging circuitry 150 are coupled to the multiplexer circuitry 160 and the controller circuitry 165. An example of the charging circuitry is illustrated and described in connection with FIGS. 2, 3, and 4, below.

The capacitor circuitry 155 has a first terminal, a second terminal, a third terminal, a fourth terminal, a fifth terminal, and a sixth terminal. The first and second terminals of the capacitor circuitry 155 are coupled to the charging circuitry 150. The third, fourth, fifth, and sixth terminals of the capacitor circuitry 155 are coupled to the multiplexer circuitry 160. An example of the capacitor circuitry 155 is illustrated and described in connection with FIGS. 2, 3, and 4, below.

The multiplexer circuitry 160 has a first terminal, a second terminal, a third terminal, a fourth terminal, a fifth terminal, a sixth terminal, a seventh terminal, and an eighth terminal. The first, second, third, and fourth terminals of the multiplexer circuitry 160 are coupled to the capacitor circuitry 155. The fifth and sixth terminals of the multiplexer circuitry 160 are coupled to the charging circuitry 150 and the controller circuitry 165. The seventh and eighth terminals of the multiplexer circuitry 160 are coupled to the comparator circuitry 170. An example of the multiplexer circuitry 160 and configurations of the multiplexer circuitry 160 are illustrated and described in connection with FIGS. 2, 3, and 4, below.

The controller circuitry 165 has a first terminal, a second terminal, and a third terminal. The first terminal of the controller circuitry 165 is coupled to the current source circuitry 130, 135 and may be coupled to external circuitry that is structured to supply the low-side control signal. The second and third terminals of the controller circuitry 165 are coupled to the charging circuitry 150 and the multiplexer circuitry 160. An example of the controller circuitry 165 is illustrated and described in connection with FIG. 2, below.

The comparator circuitry 170 has a first terminal, a second terminal, and an output terminal. The first and second terminals of the comparator circuitry 170 are coupled to the multiplexer circuitry 160. The output terminal of the comparator circuitry 170 is coupled to the current source circuitry 135. An example of the comparator circuitry 170 is illustrated and described in connection with FIGS. 2, 3, and 4, below.

In example operations of the drive system 100, the driver circuitry 105 receives the high-side and low-side control signals from external circuitry structured to control the driver circuitry 105. In some examples, the external circuitry controls the operations of the motor 110 responsive to adjusting the control signals. For example, increasing the duty cycle of the high-side control signal and decreasing the duty cycle of the low-side control signals increases the amount of power supplied to the motor 110. In such an example, the motor 110 supplies additional mechanical energy responsive to the increase in power from the driver circuitry 105.

In example operations of the driver circuitry 105, the gate driver circuitry 120, 125 independantely controls switching of the power stage circuitry 115. In some examples, the power stage circuitry 115 supplies power to the motor 110 responsive to current from the high-side gate driver circuitry 120. In such examples, the power stage circuitry 115 discharges energy from the motor 110 responsive to the low-side gate driver circuitry 125 sinking current from the motor 110. In response to the gate driver circuitry 125 transitioning from supplying current to sinking current from the motor 110, currents through the motor 110 rapidly change directions, which stresses electrical components of the motor 110. In the example of FIG. 1, the gate driver circuitry 125 decreases the amount of stress put on the motor 110 during switching events using the current multiplication circuitry 145 and the current source circuitry 135 to control the gate drive current, which controls switching. Example operations of the gate driver circuitry 125 to reduce stress on the motor 110 and increase energy efficiency are described in connection with FIGS. 2, 3, 4, 5, 6, and 7, below.

FIG. 2 is a schematic diagram of an example drive system 200, which is an example of the drive system 100 of FIG. 1. In the example of FIG. 2, the drive system 200 includes example driver circuitry 202 and an example load 204. The example driver circuitry 202 of FIG. 2 includes example power stage circuitry 206, example high-side gate driver circuitry 208, and example low-side gate driver circuitry 210. The example power stage circuitry 206 of FIG. 2 includes a first example transistor 214 and a second example transistor 216. The example low-side gate driver circuitry 210 of FIG. 2 includes first example current source circuitry 218, second example current source circuitry 220, a first example capacitor 222, example current multiplication circuitry 224, example charging circuitry 226, example capacitor circuitry 228, example multiplexer circuitry 230, example controller circuitry 232, and example comparator circuitry 233.

The example current multiplication circuitry 224 of FIG. 2 includes a third example transistor 234, a fourth example transistor 236, a fifth example transistor 238, and a sixth example transistor 240. The example charging circuitry 226 of FIG. 2 includes a seventh example transistor 242, a first example switch 244, an eighth example transistor 246, and a second example switch 248. The example capacitor circuitry 228 of FIG. 2 includes a second example capacitor 250, a third example capacitor 252, a fourth example capacitor 254, and a fifth example capacitor 256. The example multiplexer circuitry 230 of FIG. 2 includes a third example switch 258, a fourth example switch 260, a fifth example switch 262, and a sixth example switch 264. The example controller circuitry 232 of FIG. 2 includes a first example inverter 266, an example buffer 268, an example flip-flop 270, and a second example inverter 272.

The driver circuitry 202 is coupled to the load 204. The driver circuitry 202 may be coupled to external circuitry structured to supply the high-side and low-side control signals. The driver circuitry 202 is an example of the driver circuitry 105 of FIG. 1. The load 204 is coupled to the driver circuitry 202. In some examples, the load 204 may be mechanically or electrically coupled to one or more components. In some examples, the load 204 represents the motor 110 of FIG. 1.

The power stage circuitry 206 is coupled to the load 204 and the gate driver circuitry 208, 210. The power stage circuitry 206 is an example of the power stage circuitry 115 of FIG. 1. The gate driver circuitry 208 is coupled to the power stage circuitry 206 and may be coupled to external circuitry that is structured to supply the high-side supply signal. The gate driver circuitry 208 is an example of the gate driver circuitry 120 of FIG. 1. The gate driver circuitry 210 is coupled to the power stage circuitry 206 and may be coupled to external circuitry that is structured to supply the low-side supply signal. The gate driver circuitry 210 is an example of the gate driver circuitry 125 of FIG. 1.

The transistor 214 has a first terminal, a second terminal, a third terminal, and a control terminal. The first terminal of the transistor 214 is coupled to a first supply terminal, which supplies a first supply voltage (V_{SUP_1}). The second and third terminals of the transistor 214 are coupled to the load 204, the gate driver circuitry 210, and the transistor 216. In some examples, the third terminal of the transistor 214 is referred to as a bulk terminal. The control terminal of the transistor 214 is coupled to the gate driver circuitry 208. In some examples, the transistor 214 is referred to as a high-side transistor, which supplies the first supply voltage to the load 204 based on a high-side drive current from the gate driver circuitry 208.

The transistor 216 has a first terminal, a second terminal, a third terminal, and a control terminal. The first terminal of the transistor 216 is coupled to the load 204, the gate driver circuitry 210, and the transistor 214. The second and third terminals of the transistor 216 are coupled to a common terminal, which supplies a common potential (e.g., ground, AVSS, etc.). In some examples, the third terminal of the transistor 214 is referred to as the bulk terminal. The control terminal of the transistor 216 is coupled to the gate driver circuitry 210. In some examples, the transistor 216 is referred to as a low-side transistor, which provides a current path to the common potential based on a low-side drive current from the gate driver circuitry 210.

The current source circuitry 218 is coupled to the power stage circuitry 206, the current source circuitry 220, the current multiplication circuitry 224, the controller circuitry 232, and may be coupled to the external circuitry that is structured to supply the low-side control signal. The current source circuitry 218 is an example of the current source circuitry 130 of FIG. 1. The current source circuitry 220 is coupled to the power stage circuitry 206, the current source circuitry 218, the current multiplication circuitry 224, the controller circuitry 232, the comparator circuitry 233, and may be coupled to the external circuitry that is structured to supply the low-side control signal. The current source circuitry 220 is an example of the current source circuitry 135 of FIG. 1.

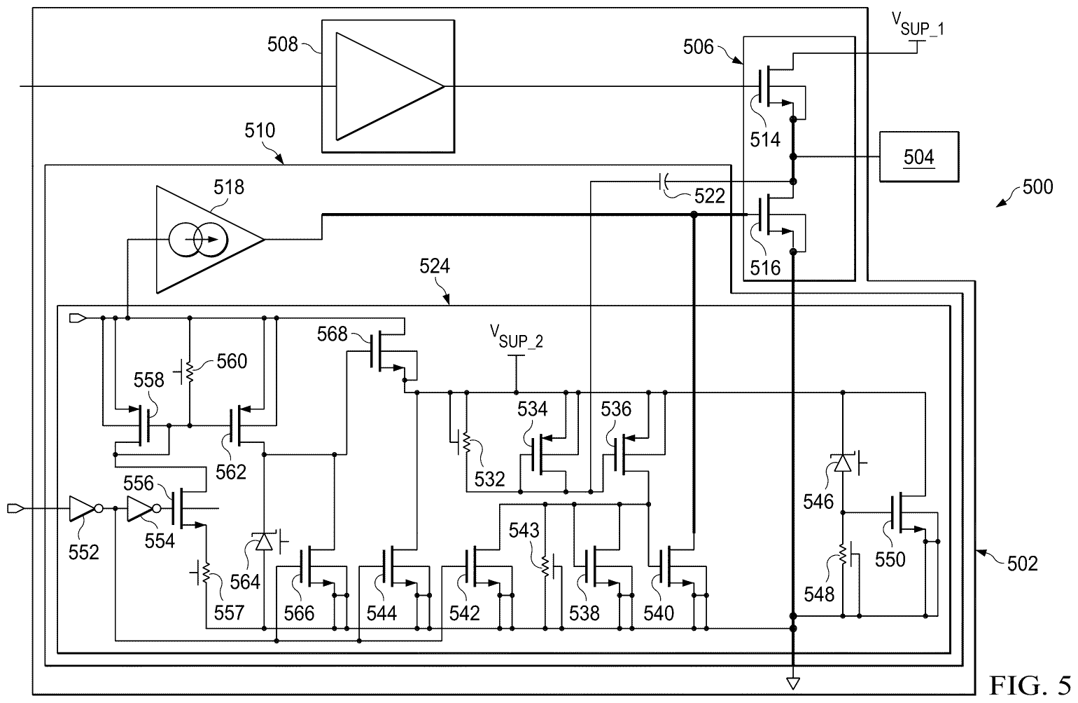

The capacitor 222 has a first terminal and a second terminal. The first terminal of the capacitor 222 is coupled to the load 204 and the transistors 214, 216. The second terminal of the capacitor 222 is coupled to the current multiplication circuitry 224 and the charging circuitry 226. The capacitor 222 is an example of the capacitor 140 of FIG. 1. The current multiplication circuitry 224 is coupled to the power stage circuitry 206, the current source circuitry 218, 220, the capacitor 222, and the charging circuitry 226. The current multiplication circuitry 224 is an example of the current multiplication circuitry 145 of FIG. 1. Another example of the current multiplication circuitry 145, 224 is illustrated and described in connection with FIG. 5, below.

In some examples, the capacitor 222 has a capacitance that is proportional to a gate-to-drain capacitance (Cgd) of the transistor 216. In such examples, the current multiplication circuitry 224 uses the capacitor 222 to compensate for the transistor 216 having a relatively low gate-to-drain capacitance, such as when the transistor 216 is a gallium nitride substrate (GaN) transistor. Advantageously, the current multiplication circuitry 224 compensates for a relatively low gate-to-drain capacitance of the transistor 216 using the capacitor 222.

The charging circuitry 226 is coupled to the capacitor 222, the current multiplication circuitry 224, the capacitor circuitry 228, the multiplexer circuitry 230, and the controller circuitry 232. The charging circuitry 226 is an example of the charging circuitry 150 of FIG. 1. The capacitor circuitry 228 is coupled to the charging circuitry 226 and the multiplexer circuitry 230. The capacitor circuitry 228 is an example of the capacitor circuitry 155 of FIG. 1. The multiplexer circuitry 230 is coupled to the charging circuitry 226, the capacitor circuitry 228, the controller circuitry 232, and the comparator circuitry 233. The multiplexer circuitry 230 is an example of the multiplexer circuitry 160 of FIG. 1. The controller circuitry 232 is coupled to the current source circuitry 130, 135, the charging circuitry 150, the multiplexer circuitry 160, and may be coupled to the external circuitry that is structured to supply the low-side control signal. The controller circuitry 232 is an example of the controller circuitry 165 of FIG. 1. The comparator circuitry 233 is coupled to the current source circuitry 220 and the multiplexer circuitry 230. The comparator circuitry 233 is an example of the comparator circuitry 170 of FIG. 1.

The transistor 234 has a first terminal, a second terminal, a third terminal, and a control terminal. The first and second terminals of the transistor 234 are coupled to a second supply terminal, which supplies a second supply voltage (V_{SUP_2}). In some examples, the second supply voltage is less than the first supply voltage. In such examples, the second supply voltage allows the gate driver circuitry 210 to use relatively lower voltage transistors, which are capable of switching at higher speeds. In some examples, the second terminal of the transistor 234 is referred to as a bulk terminal. The third and control terminals of the transistor 234 are coupled to the capacitor 222, the charging circuitry 226, and the transistor 236. In the example of FIG. 2, the transistor 234 is structured as diode circuitry, which regulates the direction of current supplied to the capacitor 222. In some examples, the transistor 234 is illustrated and described as diode circuitry. Alternatively, the current multiplication circuitry 224 may be modified to replace or illustrate the transistor 234 using diode circuitry.

The transistor 236 has a first terminal, a second terminal, a third terminal, and a control terminal. The first and second terminals of the transistor 236 are coupled to the second supply terminal, which supplies the second supply voltage. In some examples, the second terminal of the transistor 236 is referred to as a bulk terminal. The third terminal of the transistor 236 is coupled to the transistors 238, 240. The control terminal of the transistor 236 is coupled to the capacitor 222, the charging circuitry 226, and the transistor 234. In the example of FIG. 2, the transistor 236 is structured as current mirror circuitry. In some examples, the transistor 236 mirrors the current flowing through the transistor 234. Alternatively, the current multiplication circuitry 224 may be modified to replace or illustrate one or both of the transistors 234, 236 as current mirror circuitry.

The transistor 238 has a first terminal, a second terminal, a third terminal, and a control terminal. The first and control terminals of the transistor 238 are coupled to the transistors 236, 240. The second and third terminals of the transistor 238 are coupled to the common terminal, which supplies the common potential. In some examples, the third terminal of the transistor 238 is referred to as a bulk terminal. In the example of FIG. 2, the transistor 238 is structured as current mirror circuitry. In some examples, the transistor 238 mirrors the current flowing through the transistor 236. Alternatively, the current multiplication circuitry 224 may be modified to replace or illustrate the transistor 238 as current mirror circuitry.

The transistor 240 has a first terminal, a second terminal, a third terminal, and a control terminal. The first terminal of the transistor 240 is coupled to the transistor 216 and the current source circuitry 218, 220. The second and third terminals of the transistor 240 are coupled to the common terminal, which supplies the common potential. In some examples, the third terminal of the transistor 240 is referred to as a bulk terminal. The control terminal of the transistor 240 is coupled to the transistors 236, 238. In the example of FIG. 2, the transistor 240 is structured as current scaling circuitry. In some examples, the transistor 240 scales the current flowing through the transistor 238. Alternatively, the current multiplication circuitry 224 may be modified to replace or illustrate one or both of the transistors 238, 240 as current scaling circuitry.

The transistor 242 has a first terminal, a second terminal, a third terminal, and a control terminal. The first and second terminals of the transistor 242 are coupled to the second supply terminal, which supplies the second supply voltage. In some examples, the second terminal of the transistor 242 is referred to as a bulk terminal. The third terminal of the transistor 242 is coupled to the switch 244. The control terminal of the transistor 242 is coupled to the capacitor 222, the current multiplication circuitry 224, and the transistor 246. In the example of FIG. 2, the transistor 242 is structured as control circuitry that, when enabled, supplies current to the switch 244. Alternatively, the current multiplication circuitry 224 may be modified to replace or illustrate the transistor 242 as control circuitry.

The switch 244 has a first terminal, a second terminal, and a control terminal. The first terminal of the switch 244 is coupled to the transistor 242. The second terminal of the switch 244 is coupled to the capacitor circuitry 228. The control terminal of the switch 244 is coupled to the multiplexer circuitry 230 and the controller circuitry 232.

The transistor 246 has a first terminal, a second terminal, a third terminal, and a control terminal. The first and second terminals of the transistor 246 are coupled to the second supply terminal, which supplies the second supply voltage. In some examples, the second terminal of the transistor 246 is referred to as a bulk terminal. The third terminal of the transistor 246 is coupled to the capacitor circuitry 228. The control terminal of the transistor 246 is coupled to the capacitor 222, the current multiplication circuitry 224, and the transistor 242. In the example of FIG. 2, the transistor 246 is structured as control circuitry that, when enabled, supplies current to the switch 248. Alternatively, the current multiplication circuitry 224 may be modified to replace or illustrate the transistor 246 as control circuitry.

The switch 248 has a first terminal, a second terminal, and a control terminal. The first terminal of the switch 248 is coupled to the transistor 246. The second terminal of the switch 248 is coupled to the capacitor circuitry 228. The control terminal of the switch 248 is coupled to the multiplexer circuitry 230 and the controller circuitry 232. In some examples, the switches 244, 248 are implemented using transistors. In other examples, the charging circuitry 226 may be modified to implement the switches 244, 248 as switching circuitry or in combination with the transistors 242, 246.

The capacitor 250 has a first terminal and a second terminal. The first terminal of the capacitor 250 is coupled to the charging circuitry 226 and the multiplexer circuitry 230. The second terminal of the capacitor 250 is coupled to the charging circuitry 226, the multiplexer circuitry 230, and the capacitor 254. The capacitor 252 has a first terminal and a second terminal. The first terminal of the capacitor 252 is coupled to the charging circuitry 226 and the multiplexer circuitry 230. The second terminal of the capacitor 252 is coupled to the charging circuitry 226, the multiplexer circuitry 230, and the capacitor 256.

The capacitor 254 has a first terminal and a second terminal. The first terminal of the capacitor 254 is coupled to the multiplexer circuitry 230 and the capacitor 250. The second terminal of the capacitor 254 is coupled to the common terminal, which supplies the common potential. The capacitor 256 has a first terminal and a second terminal. The first terminal of the capacitor 256 is coupled to the multiplexer circuitry 230 and the capacitor 252. The second terminal of the capacitor 256 is coupled to the common terminal, which supplies the common potential.

In the example of FIG. 2, the capacitors 250, 254 are referred to as a set of first capacitors 250, 254 and the capacitors 252, 256 are referred to as a set of second capacitors 252, 256. When the charging circuitry 226 is structured to charge (as further described below) the set of first capacitors 250, 254, the set of first capacitors 250, 254 generate a switching voltage at the first terminal of the capacitor 250. When the charging circuitry 226 is not structured to charge (as further described below) the set of first capacitors 250, 254, the set of first capacitors 250, 254 supply a reference voltage at the second terminal of the capacitor 250 and the first terminal of the capacitor 254.

Similarly, when the charging circuitry 226 is structured to charge the set of second capacitors 252, 256, the set of second capacitors 252, 256 generate the switching voltage at the first terminal of the capacitor 252. Also, when the charging circuitry 226 is structured to discharge the set of second capacitors 252, 256, the set of second capacitors 252, 256 generate the reference voltage at the second terminal of the capacitor 252 and the first terminal of the capacitor 256. Advantageously, the charging circuitry 226 may cause either the set of first capacitors 250, 254 or the set of second capacitors 252, 256 to generate either one of the reference voltage or the switching voltage. Advantageously, the reference voltage represents a discharge of the capacitor circuitry 228 and the switching voltage represents a charging of the capacitor circuitry 228.

The switch 258 has a first terminal, a second terminal, and a control terminal. The first terminal of the switch 258 is coupled to the charging circuitry 226 and the capacitor circuitry 228. The second terminal of the switch 258 is coupled to the switch 260 and the comparator circuitry 233. The control terminal of the switch 258 is coupled to the charging circuitry 226, the controller circuitry 232, and the switch 262. The switch 258 is structured to receive the switching voltage from the set of second capacitors 252, 256.

The switch 260 has a first terminal, a second terminal, and a control terminal. The first terminal of the switch 260 is coupled to the charging circuitry 226 and the capacitor circuitry 228. The second terminal of the switch 260 is coupled to the switch 258 and the comparator circuitry 233. The control terminal of the switch 260 is coupled to the charging circuitry 226, the controller circuitry 232, and the switch 264. The switch 260 is structured to receive the switching voltage from the set of first capacitors 250, 254.

The switch 262 has a first terminal, a second terminal, and a control terminal. The first terminal of the switch 262 is coupled to the capacitor circuitry 228. The second terminal of the switch 262 is coupled to the switch 264 and the comparator circuitry 233. The control terminal of the switch 262 is coupled to the charging circuitry 226, the controller circuitry 232, and the switch 258. The switch 262 is structured to receive the reference voltage from the set of first capacitors 250, 254.

The switch 264 has a first terminal, a second terminal, and a control terminal. The first terminal of the switch 264 is coupled to the capacitor circuitry 228. The second terminal of the switch 264 is coupled to the switch 262 and the comparator circuitry 233. The control terminal of the switch 264 is coupled to the charging circuitry 226, the controller circuitry 232, and the switch 260. The switch 264 is structured to receive the reference voltage from the set of second capacitors 252, 256.

The inverter 266 has a first terminal and a second terminal. The first terminal of the inverter 266 is coupled to the current source circuitry 218, 220 and may be coupled to the external circuitry that is structured to supply the low-side control signal. The second terminal of the inverter 266 is coupled to the flip-flop 270. In the example of FIG. 2, the inverter 266 is structured to invert the low-side control signal. Alternatively, the controller circuitry 232 may be modified to receive an inverted replica of the low-side control signal. In such an example, the controller circuitry 232 may be modified to remove the inverter 266. The buffer 268 has a first terminal and a second terminal. The first terminal of the buffer 268 is coupled to a reset terminal, which supplies a reset signal. The second terminal of the buffer 268 is coupled to the flip-flop 270. In the example of FIG. 2, the buffer 268 is structured to have propagation delay approximately equal to a propagation delay of the inverter 266.

The flip-flop 270 has a clock terminal (CLK), a clear terminal (CLR), a data terminal (D), an output terminal (Q), and an inverted output terminal (QZ). The clock terminal of the flip-flop 270 is coupled to the inverter 266. The clear terminal of the flip-flop 270 is coupled to the buffer 268. The data terminal of the flip-flop 270 is coupled to the inverted output terminal of the flip-flop 270. The output terminal of the flip-flop 270 is coupled to the charging circuitry 226, the multiplexer circuitry 230, and the inverter 272. In the example of FIG. 2, the flip-flop 270 is a data (D) flip-flop. Alternatively, the controller circuitry 232 may be modified to use an alternative type of flip-flop. The flip-flop 270 is structured as divider circuitry, which generates a first switching signal by dividing the frequency of the low-side control signal. The flip-flop 270 uses the first switching signal to control the switches 248, 258, 262.

The inverter 272 has a first terminal and a second terminal. The first terminal of the inverter 272 is coupled to the charging circuitry 226, the multiplexer circuitry 230, and the flip-flop 270. The second terminal of the inverter 272 is coupled to the charging circuitry 226 and the multiplexer circuitry 230. The inverter 272 is structured to generate a second switching signal by inverting the first switching signal from the flip-flop 270. The inverter 272 uses the second switching signal to control the switches 244, 260, 264.

During example operations of the drive system 200, the gate driver circuitry 210 controls the transistor 216 responsive to receiving the low-side control signal. During example operations to turn on the transistor 216 (e.g., enable, conducting, etc.), the controller circuitry 232 uses the first and second switching signals to structure the charging circuitry 226 and the multiplexer circuitry 230 to support a multi-slew turn on of the transistor 216. In some such example operations, the gate driver circuitry 210 uses a first current to drive the transistor 216 for a first duration of time. However, in response to the comparator circuitry 233 determining that the switching voltage from the capacitor circuitry 228 is greater than or equal to the reference voltage from the capacitor circuitry 228, the comparator circuitry 233 disables the current source circuitry 220. After such a determination, the gate driver circuitry 210 uses a second current, which is less than the first current, to drive the transistor 216. Advantageously, during the first duration of time, the current through the transistor 216 has a relatively high slew rate, which increases power efficiency, and after the first duration the current through the transistor 216 has a relatively low slew rate, which decreases stress on components of the load 204. Advantageously, initially using a relatively high slew rate improves power efficiency during switching operations.

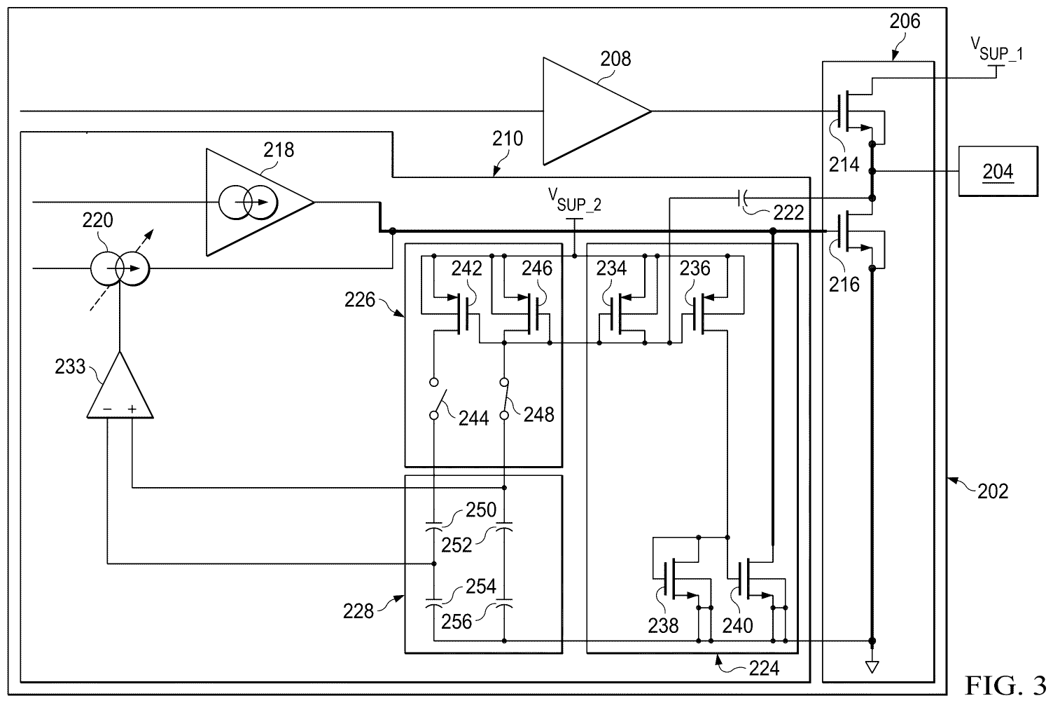

FIG. 3 is a schematic diagram of a first configuration of the example drive system 200 of FIG. 2, which is an example of the drive system 100 of FIG. 1. In the example of FIG. 3, the drive system 200 is structured to supply a reference voltage using the set of first capacitors 250, 254 of FIG. 2 and generate a switching voltage by charging the set of second capacitors 252, 256 of FIG. 2. In such example operations, the controller circuitry 232 of FIG. 2 opens the switches 244, 260, 264 of FIG. 2 and closes the switches 248, 258, 262 of FIG. 2. When in the first configuration of FIG. 3, the comparator circuitry 233 of FIG. 2 controls the current source circuitry 220 of FIG. 2 responsive to a comparison of the reference voltage from the set of first capacitors 250, 254 to the switching voltage from the set of second capacitors 252, 256.

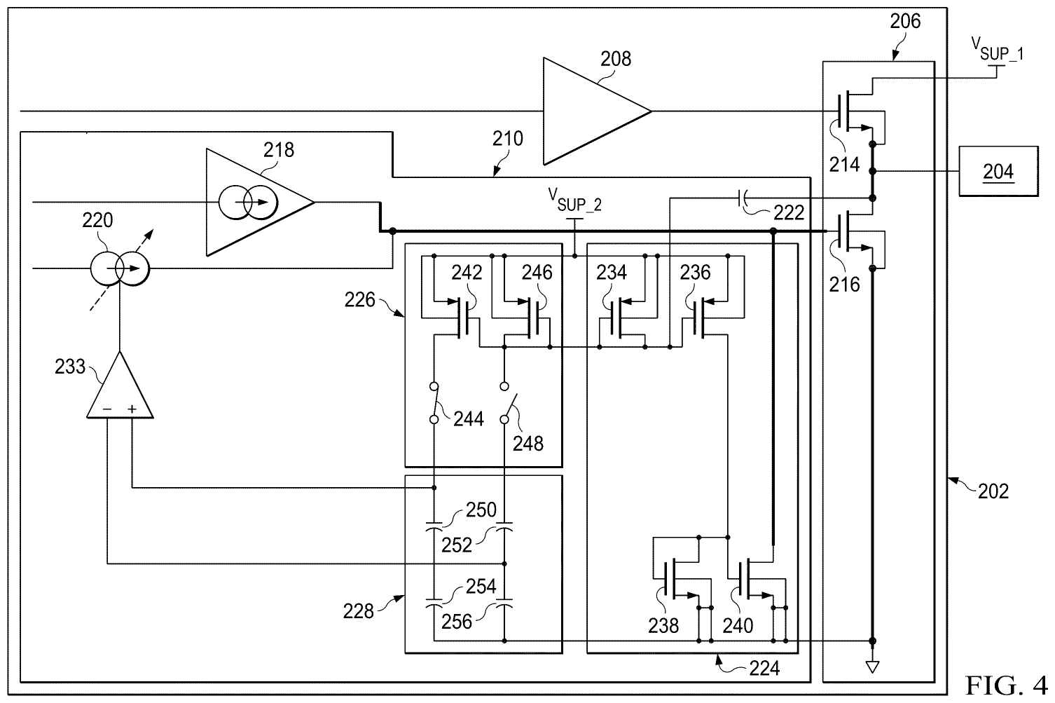

FIG. 4 is a schematic diagram of a second configuration of the example drive system 200 of FIG. 2, which is an example of the drive system 100 of FIG. 1. In the example of FIG. 4, the drive system 200 is structured to generate a switching voltage by charging the set of first capacitors 250, 254 of FIG. 2 and supply a reference voltage using the set of second capacitors 252, 256 of FIG. 2. In such example operations, the controller circuitry 232 of FIG. 2 closes the switches 244, 260, 264 of FIG. 2 and opens the switches 248, 258, 262 of FIG. 2. When in the second configuration of FIG. 4, the comparator circuitry 233 of FIG. 2 controls the current source circuitry 220 of FIG. 2 responsive to a comparison of the switching voltage from the set of first capacitors 250, 254 to the reference voltage from the set of second capacitors 252, 256.

In the example of FIGS. 2, 3, and 4, the transistors 214, 216, 238, 240 are n-channel metal-oxide semiconductor field-effect transistors (MOSFETs). Alternatively, the transistors 214, 216, 238, 240 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. In the example of FIGS. 2, 3, and 4, the transistors 234, 236, 242, 246 are p-channel MOSFETs. Alternatively, the transistors 234, 236, 242, 246 may be p-channel FETs, p-channel IGBTs, p-channel JFETs, NPN BJTs, or, with slight modifications, N-type equivalent devices. The transistors 214, 216, 234, 236, 238, 240, 242, 246 may be depletion mode devices, drain-extended devices, enhancement mode devices, natural transistors or other type of device structure transistors. Furthermore, the transistors 214, 216, 234, 236, 238, 240, 242, 246 may be implemented in/over a silicon substrate (Si), a silicon carbide substrate (SiC), a gallium nitride substrate (GaN) or a gallium arsenide substrate (GaAs).

FIG. 5 is a schematic diagram of an example drive system 500, which is another example of the drive systems 100, 200 of FIGS. 1, 2, 3, and 4, that includes another example of current multiplication circuitry 145, 224 of FIGS. 1, 2, 3, and 4. In the example of FIG. 5, the drive system 500 includes example driver circuitry 502 and an example load 504. The driver circuitry 502 of FIG. 5 includes example power stage circuitry 506, example high-side gate driver circuitry 508, and example low-side gate driver circuitry 510. The power stage circuitry 506 of FIG. 5 includes a first example transistor 514 and a second example transistor 516.

The example low-side gate driver circuitry 510 of FIG. 5 includes example current source circuitry 518, an example capacitor 522, and example current multiplication circuitry 524. The current multiplication circuitry 524 of FIG. 5 includes a first example resistor 532, a third example transistor 534, a fourth example transistor 536, a fifth example transistor 538, a sixth example transistor 540, a seventh example transistor 542, a second example resistor 543, an eighth example transistor 544, a first example diode 546, a third example resistor 548, a ninth example transistor 550, a first example inverter 552, a second example inverter 554, a tenth example transistor 556, a fourth example resistor 557, an eleventh example transistor 558, a fifth example resistor 560, a twelfth example transistor 562, a second example diode 564, a thirteenth example transistor 566, and a fourteenth example transistor 568. In the example of FIG. 5, the gate driver circuitry 510 implements single slew rate switching using the current source circuitry 518. Alternatively, the gate driver circuitry 510 may be modified to implement multi slew rate switching, as shown in FIGS. 2, 3, and 4.

The driver circuitry 502 is coupled to the load 504. The driver circuitry 502 may be coupled to external circuitry that is structured to supply the high-side and low-side control signals. The driver circuitry 502 is an alternative example of the driver circuitry 105, 202 of FIGS. 1, 2, 3, and 4. In the example of FIG. 5, the driver circuitry 502 includes the current multiplication circuitry 524, which further includes circuitry to reduce a quiescent current during times that the transistor 516 is off. The load 504 is coupled to the driver circuitry 502. In some examples, the load 504 may be mechanically or electrically coupled to one or more components. The load 504 is another example of the motor 110 of FIG. 1 and the load 204 of FIGS. 2, 3, and 4.

The power stage circuitry 506 is coupled to the load 504 and the gate driver circuitry 508, 510. The power stage circuitry 506 is another example of the power stage circuitry 115, 206 of FIGS. 1, 2, 3, and 4. The gate driver circuitry 508 is coupled to the power stage circuitry 506 and may be coupled to external circuitry that is structured to supply the high-side supply signal. The gate driver circuitry 508 is another example of the gate driver circuitry 120, 208 of FIGS. 1, 2, 3, and 4. The gate driver circuitry 510 is coupled to the power stage circuitry 506 and may be coupled to external circuitry that is structured to supply the low-side supply signal. The gate driver circuitry 510 is an example of the gate driver circuitry 125, 210 of FIGS. 1, 2, 3, and 4.

The transistor 514 has a first terminal, a second terminal, a third terminal, and a control terminal. The first terminal of the transistor 514 is coupled to the first supply terminal, which supplies the first supply voltage (V_{SUP_1}). The second and third terminals of the transistor 514 are coupled to the load 504, the gate driver circuitry 510, and the transistor 516. In some examples, the third terminal of the transistor 514 is referred to as a bulk terminal. The control terminal of the transistor 514 is coupled to the gate driver circuitry 508. In some examples, the transistor 514 is referred to as a high-side transistor, which supplies the supply voltage to the load 504 based on a high-side drive current from the gate driver circuitry 508. The transistor 514 is an example of the transistor 214 of FIGS. 2, 3, and 4.

The transistor 516 has a first terminal, a second terminal, a third terminal, and a control terminal. The first terminal of the transistor 516 is coupled to the load 504, the gate driver circuitry 510, and the transistor 514. The second and third terminals of the transistor 516 are coupled to the common terminal, which supplies the common potential. In some examples, the third terminal of the transistor 514 is referred to as the bulk terminal. The control terminal of the transistor 516 is coupled to the gate driver circuitry 510. In some examples, the transistor 516 is referred to as a low-side transistor, which provides a current path to the common potential based on a low-side drive current from the gate driver circuitry 510. The transistor 516 is an example of the transistor 216 of FIGS. 2, 3, and 4.

The current source circuitry 518 is coupled to the power stage circuitry 506, the current multiplication circuitry 524, and may be coupled to external circuitry that is structured to supply the low-side control signal. The current source circuitry 518 is another example of the current source circuitry 130, 218 of FIGS. 1, 2, 3, and 4. The capacitor 522 has a first terminal and a second terminal. The first terminal of the capacitor 522 is coupled to the load 504 and the transistors 514, 516. The second terminal of the capacitor 522 is coupled to the current multiplication circuitry 524. The capacitor 522 is another example of the capacitors 140, 222 of FIGS. 1, 2, 3, and 4.

The current multiplication circuitry 524 is coupled to the power stage circuitry 506, the current source circuitry 518, the capacitor 522, and the external circuitry that is structured to supply the low-side control signal. The current multiplication circuitry 524 is another example of the current multiplication circuitry 145, 224 of FIGS. 1, 2, 3, and 4. In the example of FIG. 5, the current multiplication circuitry 524 includes additional circuitry that reduces the quiescent current by disabling components when the transistor 516 is off.

In some examples, the capacitor 522 has a capacitance that is proportional to a non-ideal gate-to-drain capacitance of the transistor 516. In such examples, the current multiplication circuitry 524 is structured to use the capacitor 522 to compensate for the transistor 516 having a relatively low gate-to-drain capacitance, such as when the transistor 516 is a gallium nitride substrate (GaN) transistor. Advantageously, the current multiplication circuitry 524 is structured to compensate for a relatively low gate-to-drain capacitance of the transistor 516 using a relatively small capacitance.

The resistor 532 has a first terminal and a second terminal. The first terminal of the resistor 532 is coupled to the second supply terminal, which supplies the second supply voltage (V_{SUP_2}). The second terminal of the resistor 532 is coupled to the capacitor 522 and the transistors 534, 536. In some examples, the resistor 532 is structured as discharge circuitry, which prevents the control terminals of the transistors 534, 536 from floating when no signal is present (also referred to as deadtime). Alternatively, the current multiplication circuitry 524 may be modified to exclude the resistor 532 or implement another method of discharging the control terminals of the transistors 534, 536.

The transistor 534 has a first terminal, a second terminal, a third terminal, and a control terminal. The first and second terminals of the transistor 534 are coupled to the second supply terminal, which supplies the second supply voltage. In some examples, the second terminal of the transistor 534 is referred to as a bulk terminal. The third and control terminals of the transistor 534 are coupled to the capacitor 522, the resistor 532, and the transistor 536. In the example of FIG. 5, the transistor 534 is structured as diode circuitry, which regulates the direction of current supplied to the capacitor 522. In some examples, the transistor 534 is illustrated and described as diode circuitry. Alternatively, the current multiplication circuitry 524 may be modified to replace or illustrate the transistor 534 using diode circuitry.

The transistor 536 has a first terminal, a second terminal, a third terminal, and a control terminal. The first and second terminals of the transistor 536 are coupled to the second supply terminal, which supplies the second supply voltage. In some examples, the second terminal of the transistor 536 is referred to as a bulk terminal. The third terminal of the transistor 536 is coupled to the transistors 538, 540, 542 and the resistor 543. The control terminal of the transistor 536 is coupled to the capacitor 522, the resistor 532, and the transistor 534. In the example of FIG. 5, the transistor 536 is structured as current mirror circuitry. In some examples, the transistor 536 mirrors the current flowing through the transistor 534. Alternatively, the current multiplication circuitry 524 may be modified to replace or illustrate one or both of the transistors 534, 536 using current mirror circuitry.

The transistor 538 has a first terminal, a second terminal, a third terminal, and a control terminal. The first and control terminals of the transistor 538 are coupled to the transistors 536, 540, 542, and the resistor 543. The second and third terminals of the transistor 538 are coupled to the common terminal, which supplies the common potential. In some examples, the third terminal of the transistor 538 is referred to as a bulk terminal. In the example of FIG. 5, the transistor 538 is structured as current mirror circuitry. In some examples, the transistor 538 mirrors the current flowing through the transistor 536. Alternatively, the current multiplication circuitry 524 may be modified to replace or illustrate the transistor 538 using current mirror circuitry.

The transistor 540 has a first terminal, a second terminal, a third terminal, and a control terminal. The first terminal of the transistor 540 is coupled to the transistor 516 and the current source circuitry 518. The second and third terminals of the transistor 540 are coupled to the common terminal, which supplies the common potential. In some examples, the third terminal of the transistor 540 is referred to as a bulk terminal. The control terminal of the transistor 540 is coupled to the transistors 536, 538, 542 and the resistor 543. In the example of FIG. 5, the transistor 540 is structured as current scaling circuitry. In some examples, the transistor 540 scales the current flowing through the transistor 538. Alternatively, the current multiplication circuitry 524 may be modified to replace or illustrate one or both of the transistors 538, 540 using alternative current scaling circuitry.

The transistor 542 has a first terminal, a second terminal, a third terminal, and a control terminal. The first terminal of the transistor 542 is coupled to the transistors 536, 538, 540 and the resistor 543. The second and third terminal of the transistor 542 is coupled to the common terminal, which supplies the common potential. In some examples, the third terminal of the transistor 542 is referred to as a bulk terminal. The control terminal of the transistor 542 is coupled to the transistors 544, 566 and the inverters 552, 554. In the example of FIG. 5, the transistor 542 is structured as control circuitry that, when enabled, prevents the transistors 538, 540 from being turned on. Alternatively, the current multiplication circuitry 524 may be modified to replace or illustrate the transistor 542 as control circuitry.

The resistor 543 has a first terminal and a second terminal. The first terminal of the resistor 543 is coupled to the transistors 536, 538, 540, 542. The second terminal of the resistor 543 is coupled to the common terminal, which supplies the common potential. In some examples, the resistor 543 is structured as discharge circuitry, which prevents the control terminals of the transistors 538, 540 from floating when no signal is present (also referred to as deadtime). Alternatively, the current multiplication circuitry 524 may be modified to exclude the resistor 543 or implement another method of discharging the control terminals of the transistors 538, 540.

The transistor 544 has a first terminal, a second terminal, a third terminal, and a control terminal. The first terminal of the transistor 544 is coupled to the second supply terminal, which supplies the second supply voltage. The second and third terminals of the transistor 544 are coupled to the common terminal, which supplies the common potential. In some examples, the third terminal of the transistor 544 is referred to as a bulk terminal. The control terminal of the transistor 544 is coupled to the transistors 542, 566 and the inverters 552, 554. In the example of FIG. 5, the transistor 544 is structured as control circuitry that, when enabled, prevents the transistors 534, 536 from being turned on. Alternatively, the current multiplication circuitry 524 may be modified to replace or illustrate the transistor 544 with alternative control circuitry. In such examples, the transistor 544 may be illustrated as switching circuitry.

The diode 546 has a first terminal and a second terminal. The first terminal of the diode 546 is coupled to the secondary supply terminal, which supplies the second supply voltage. The second terminal of the diode 546 is coupled to the resistor 548 and the transistor 550. In the example of FIG. 5, the diode 546 is a Zener diode that is structured to breakdown (e.g., conduct current) responsive to a voltage difference greater than a threshold voltage. The resistor 548 has a first terminal and a second terminal. The first terminal of the resistor 548 is coupled to the diode 546 and the transistor 550. The second terminal of the resistor 548 is coupled to the common terminal, which supplies the common potential. The transistor 550 has a first terminal, a second terminal, a third terminal, and a control terminal. The first terminal of the transistor 550 is coupled to the second supply terminal, which supplies the second supply voltage. The second and third terminals of the transistor 550 are coupled to the common terminal, which supplies the common potential. In some examples, the third terminal of the transistor 550 is referred to as a bulk terminal. The control terminal of the transistor 550 is coupled to the diode 546 and the resistor 548.

In the example of FIG. 5, the diode 546, the resistor 548, and the transistor 550 are structured as clamp circuitry. In some examples, the diode 546, the resistor 548, and the transistor 550 prevent the second supply voltage from increasing beyond a maximum voltage by clamping the second supply voltage. For example, when the second supply voltage exceeds a breakdown voltage of the diode 546, the resistor 548 uses current from the diode 546 to turn on the transistor 550, which clamps the second supply voltage. Alternatively, the current multiplication circuitry 524 may be modified to replace or illustrate one or more of the diode 546, the resistor 548, or the transistor 550 as clamp circuitry. In such examples, one or more of the diode 546, the resistor 548, or the transistor 550 may be illustrated as clamp circuitry.

The inverter 552 has a first terminal and a second terminal. The first terminal of the inverter 552 may be coupled to external circuitry that is structured to supply the low-side control signal. The second terminal of the inverter 552 is coupled to the transistors 542, 544, 566 and the inverter 554. The inverter 554 has a first terminal and a second terminal. The first terminal of the inverter 554 is coupled to the transistors 542, 544, 566 and the inverter 552. The second terminal of the inverter 554 is coupled to the transistor 556.

The transistor 556 has a first terminal, a second terminal, and a control terminal. The first terminal of the transistor 556 is coupled to the transistors 558, 562 and the resistor 560. The second terminal of the transistor 556 is coupled to the resistor 557. The control terminal of the transistor 556 is coupled to the inverter 554. The resistor 557 has a first terminal and a second terminal. The first terminal of the resistor 557 is coupled to the transistor 556. The second terminal of the resistor 557 is coupled to the common terminal, which supplies the common potential. In some examples, the resistor 557 is a current limiting resistor, which prevents excessively high currents from flowing through the transistors 556, 558. Alternatively, the current multiplication circuitry 524 may be modified to exclude the resistor 557 or implement another method of current regulation.

The transistor 558 has a first terminal, a second terminal, a third terminal, and a control terminal. The first and second terminals of the transistor 558 are coupled to the current source circuitry 518, the resistor 560, the transistors 562, 568, and external circuitry that is structured to supply the low-side control signal. In some examples, the second terminal of the transistor 558 is referred to as a bulk terminal. The third and control terminals of the transistor 558 are coupled to the transistors 556, 562 and the resistor 560. The resistor 560 has a first terminal and a second terminal. The first terminal of the resistor 560 is coupled to the current source circuitry 518, the transistors 558, 562, 568, and external circuitry that is structured to supply the low-side control signal. The second terminal of the resistor 560 is coupled to the transistors 556, 558, 562. The transistor 562 has a first terminal, a second terminal, a third terminal, and a control terminal. The first terminal and second terminals of the transistor 562 are coupled to the current source circuitry 518, the transistors 558, 568, the resistor 560, and the external circuitry structured to supply the secondary supply voltage.

In the example of FIG. 5, the transistor 558, 562 are structured as current mirror circuitry. In some examples, the transistor 562 mirrors the current flowing through the transistor 558. Alternatively, the current multiplication circuitry 524 may be modified to replace or illustrate one or both of the transistors 558, 562 using current mirror circuitry. In such examples, the transistors 558, 562 may be illustrated as current mirror circuitry.

The diode 564 has a first terminal and a second terminal. The first terminal of the diode 564 is coupled to the transistors 562, 566, 568. The second terminal of the diode 564 is coupled to the common terminal, which supplies the common potential. In the example of FIG.

5, the diode 564 is a Zener diode that is structured to breakdown (e.g., conduct current) responsive to a voltage difference greater than a threshold voltage.

The transistor 566 has a first terminal, a second terminal, a third terminal, and a control terminal. The first terminal of the transistor 566 is coupled to the transistors 562, 568 and the diode 564. The second and third terminals of the transistor 566 are coupled to the common terminal, which supplies the common potential. The control terminal of the transistor 566 is coupled to the transistors 542, 544 and the inverters 552, 554. In the example of FIG. 5, the transistor 566 is structured as control circuitry that, when enabled, prevents the transistor 568 from being turned on. Alternatively, the current multiplication circuitry 524 may be modified to replace or illustrate the transistor 566 as control circuitry. In such examples, the transistor 566 may be illustrated as switching circuitry.

The transistor 568 has a first terminal, a second terminal, a third terminal, and a control terminal. The first terminal of the transistor 568 is coupled to the auxiliary supply terminal, which supplies the auxiliary supply voltage. The second and third terminals of the transistor 568 are coupled to the second supply terminal, which supplies the second supply voltage. The control terminal of the transistor 568 is coupled to the transistors 562, 566 and the diode 564. In the example of FIG. 5, the transistor 568 is structured as regulator circuitry. In some examples, the transistor 568 regulates the auxiliary supply voltage to set the second supply voltage. Alternatively, the current multiplication circuitry 524 may be modified to replace or illustrate the transistor 568 as regulator circuitry. In such examples, the transistor 568 may be illustrated as supply circuitry.

In the example of FIG. 5, the transistors 514, 516, 538, 540, 542, 544, 550, 556, 566, 568 are n-channel MOSFETs. Alternatively, the transistors 514, 516, 538, 540, 542, 544, 550, 556, 566, 568 may be n-channel FETs, n-channel IGBTs, n-channel JFETs, NPN BJTs. In the example of FIG. 5, the transistors 534, 536, 558, 562 are p-channel MOSFETs. Alternatively, the transistors 534, 536, 558, 562 may be p-channel FETs, p-channel IGBTs, p-channel JFETs, NPN BJTs. One or more of the transistors 514, 516, 534, 536, 538, 540, 542, 544, 550, 556, 566, 558, 562 may be depletion mode devices, drain-extended devices, enhancement mode devices, natural transistors or other type of device structure transistors. Furthermore, the transistors 514, 516, 534, 536, 538, 540, 542, 544, 550, 556, 566, 558, 562 may be implemented in/over a silicon substrate (Si), a silicon carbide substrate (SiC), a gallium nitride substrate (GaN) or a gallium arsenide substrate (GaAs).

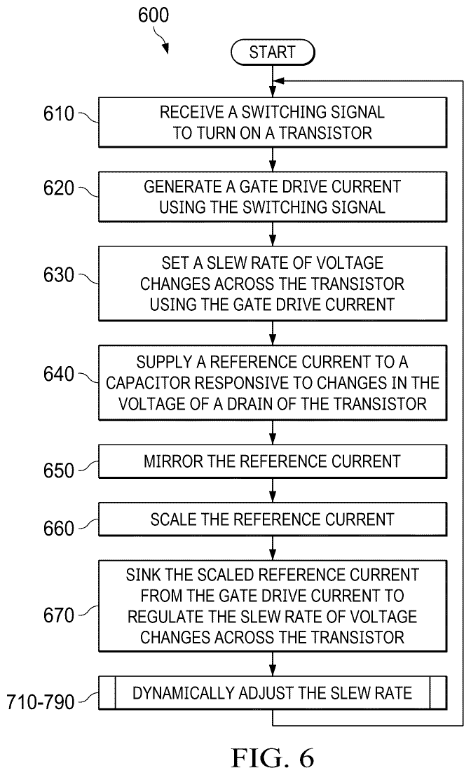

FIG. 6 is a flowchart representative of example operations 600 that may be at least one of executed, instantiated, or performed to implement the current multiplication circuitry 145, 224, 524 of FIGS. 1, 2, 3, 4, and 5 to regulate a slew-rate of a voltage across a transistor (e.g., the transistors 216, 516 of FIGS. 2, 3, 4, and 5). The example operations 600 of FIG. 6 begin at Block 610 at which the gate driver circuitry 125, 210, 510 of FIGS. 1, 2, 3, 4, and 5 receives a switching signal to turn on a transistor. (Block 610). In some examples, external circuitry supplies a low-side control signal to the gate driver circuitry 125, 210. In such examples, the low-side control signal is a pulse width modulation (PWM) signal having a duty cycle, which determines an on time and an off time of the transistors 216, 516. The on time corresponds to durations of time during which the gate driver circuitry 125, 210, 510 supplies a drive current that causes the transistors 216, 516 to conduct current. The off time corresponds to durations of time where the gate driver circuitry 125, 210, 510 does not generate a drive current capable of causing the transistor 216, 516 to conduct current. In such example operations, adjusting the duty cycle of the low-side control signal allows the external circuitry to modify a supply of power to the motor 110 of FIG. 1.

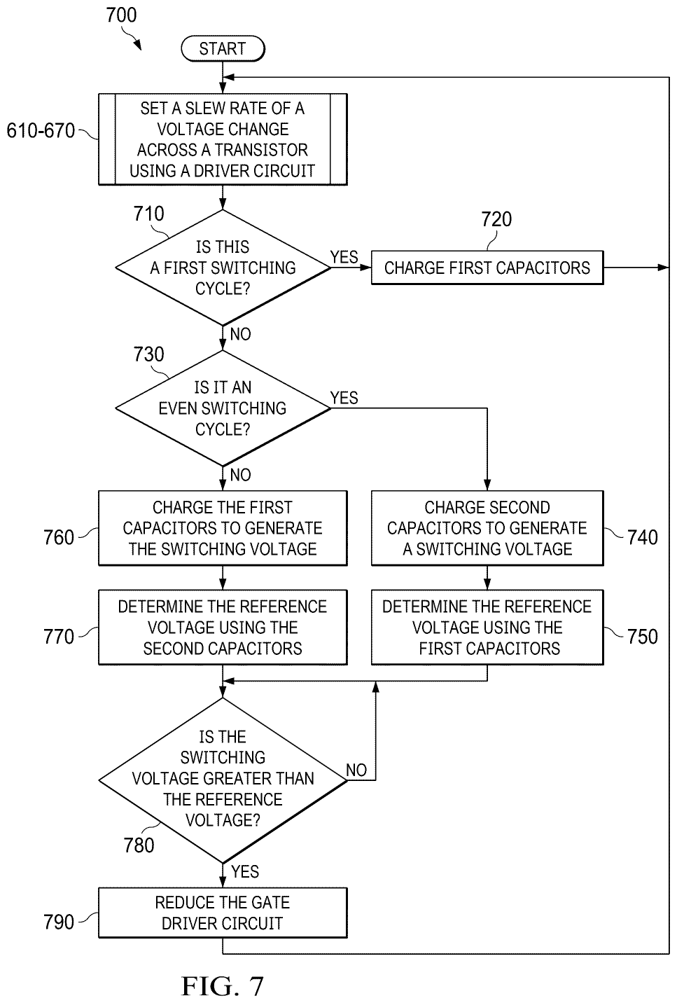

The current source circuitry 130, 135, 218, 220, 518 of FIGS. 1, 2, 3, 4, and 5 generate a gate drive current using the switching signal. (Block 620). In some examples, the current source circuitry 130, 135 218, 220, 518 supply current responsive to receiving the low-side control signal corresponding to the on time. For example, the current source circuitry 130, 135, 218, 220, 518 supply current responsive to receiving a low-side control signal that is a logic high (e.g., logical one). In such examples, currents from the current source circuitry 130, 135, 218, 220, 518 combine to generate the gate drive current. However, as described in FIG. 7, below, disabling the current source circuitry 135, 220 sets the gate drive current equal to the current from the current source circuitry 130, 218. Advantageously, the gate driver circuitry 125, 210 may modify the gate driver current using the current source circuitry 135, 220.

The current source circuitry 130, 135, 218, 220, 518 set a slew rate of voltage changes across the transistor. (Block 630). In some examples, the current source circuitry 130, 135, 218, 220, 518 set the slew rate of the transistors 216, 516 responsive to the magnitude of the gate driver current. For example, the transistors 216, 516 have a higher slew rate when the gate driver current is increased and has a lower slew rate when the gate driver current is decreased. In such examples, the current source circuitry 130 135, 218, 220, 518 are structured to supply currents that set the slew rate of the transistors 216, 516 to a designed value. Advantageously, adjusting the gate drive current adjusts the slew rate of the transistors 216, 516. Advantageously, the current source circuitry 130, 135, 218, 220 may be structured to set the slew rate of the transistors 216, 516.

The current multiplication circuitry 145, 224, 524 supplies a reference current to a capacitor responsive to changes in the voltage of a drain of the transistor. (Block 640). In some examples, the transistors 234, 534 of FIGS. 2, 3, 4, and 5 are structured as diode circuitry, which supply current to the capacitors 222, 522 of FIGS. 2, 3, 4, and 5. In example operation, once the current source circuitry 130, 135, 218, 220, 518 supplies a gate drive current to the transistors 216, 516, the voltage across the capacitors 222, 522 begins to change. The capacitors 222, 522 source current from the transistors 234, 534 responsive to changes in the voltage across the transistors 216, 516. Advantageously, the operations of the capacitor 222, 522 using the transistors 234, 534 are proportional to having a capacitor coupled between the drain and gate terminals of the transistors 216, 516.

The current multiplication circuitry 145, 224, 524 mirrors the reference current. (Block 650). In some examples, the transistors 236, 536 of FIGS. 2, 3, 4, and 5 are structured as current mirror circuitry, which mirror the current through the transistors 234, 534. In such examples, the transistors 236, 536 supply the replica of the reference current to the transistors 238, 240, 538, 540 of FIGS. 2, 3, 4, and 5. Advantageously, the transistors 234, 534 mirror the current being supplied to the capacitors 222, 522.

The current multiplication circuitry 145, 224, 524 scales the reference current. (Block 660). In some examples, the transistors 238, 538 are structured as current mirror circuitry, which sinks a current approximately equal to the replica of the reference current from the transistors 236, 536. Also, the transistors 238, 538 control the transistors 240, 540 responsive to sinking the replica of the reference current. In some examples, the transistors 240, 540 are structured as scaling circuitry, which scales the current flowing through the transistors 238, 538. In such examples, the transistors 240, 540 are sized (e.g., having characteristics that scale) in relation to the transistors 238, 538. In example operations, the transistors 240, 540 sink a current approximately equal to the ratio of the size of the transistors 240, 540 to the transistors 238, 538. For example, the transistors 240, 540 may sink a current that is approximately sixteen times the current flowing through the transistors 238, 538.

The current multiplication circuitry 145, 224, 524 sinks the scaled reference current from the gate drive current to regulate the slew rate of voltage changes across the transistor. (Block 670). In some examples, the transistors 240, 540 are structured as current sink circuitry, which sinks the scaled current from the control terminal of the transistor 216. In such examples, the transistors 240, 540 decrease the gate drive current responsive to sinking the scaled current.

Advantageously, the current multiplication circuitry 145, 224, 524 uses the scaled current to mimic having a relatively large capacitance coupled between the gate and drain terminals of the transistors 216, 516. Advantageously, the current multiplication circuitry 145, 224, 524 decreases the size of a capacitance needed to regulate the slew rate of the transistors 216, 516. For example, when an eight picofarad capacitance is needed between the gate and drain terminals of the transistors 216, 516 and the current multiplication circuitry 145, 224, 524 scales the reference current by sixteen, the capacitors 140, 222, 522 may have a capacitance of half of a picofarad (pF). In such examples, the capacitors 140, 222, 522 and the current multiplication circuitry 145, 224, 524 mimic the eight picofarad capacitance using a capacitance that is one-sixteenth the size. Advantageously, decreasing the capacitance of the capacitors 140, 222, 522 decreases the system on chip (SoC) size of the gate driver circuitry 125, 210, 510. Advantageously, in GaN designs, decreasing the capacitance of the capacitors 140, 222, 522 decreases integration complexity of the gate driver circuitry 210, 510.

In some examples, the gate driver circuitry 125, 210, 510 dynamically adjusts the slew rate. (Blocks 710, 720, 730, 740, 750, 760, 770, 780, 790 of FIG. 7). Example operations of Blocks 710, 720, 730, 740, 750, 760, 770, 780, 790 are illustrated and described in connection with FIG. 7, below. Advantageously, dynamically adjusting the slew rate of the transistors 216, 516 allows the gate driver circuitry 125, 210, 510 to increase power efficiency by first using a relatively high slew rate, then using a relatively low slew rate. Advantageously, dynamically adjusting the slew rate of the transistors 216, 516 increases power efficiency and reduces stress on the motor 110.

Although example methods are described with reference to the flowchart illustrated in FIG. 6, many other methods of implementing the current multiplication circuitry 145, 224, 524 of FIGS. 1, 2, 3, 4, and 5 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 7 is a flowchart representative of example operations 700 that may be at least one of executed, instantiated, or performed to implement the gate driver circuitry 125, 210 of FIGS. 1, 2, 3, and 4 to dynamically adjust a slew-rate of a voltage across a transistor (e.g., the transistor 216 of FIGS. 2, 3, and 4). The example operations 700 of FIG. 7 begin with Blocks 610, 620, 630, 640, 650, 660, 670 of FIG. 6 at which the gate driver circuitry 125, 210 sets a slew rate of a voltage change across a transistor using a driver current. (Blocks 610, 620, 630, 640, 650, 660, 670). Example operations of Blocks 610, 620, 630, 640, 650, 660, 670 are illustrated and described in connection with FIG. 6, above.

The controller circuitry 165, 232 of FIGS. 1 and 2 determines if this is a first switching cycle. (Block 710). In some examples, the first switching cycle is a first pulse of the low-side control signal after at least one of a power-up or a reset. In such examples, the set of first capacitors 250, 254 of FIGS. 2, 3, and 4 or the set of second capacitors 252, 256 of FIGS. 2, 3, and 4 of the capacitor circuitry 155, 228 of FIGS. 1, 2, 3, and 4 are charged. The controller circuitry 165, 232 may include additional circuitry to determine whether the switching cycle is a first switching cycle. For example, the controller circuitry 165, 232 may include an additional flip-flop that is set the first cycle after a power-up or a reset. During the first switching cycle, the comparator circuitry 170, 233 of FIGS. 1, 2, 3, and 4 compares a switching voltage from one of the set of first capacitors 250, 254 or the set of second capacitors 252, 256. The one of the set of first capacitors 250, 254 or the set of second capacitors 252, 256 generates the switching voltage responsive to being charged. However, prior to the first switching cycle, the capacitors 250, 252, 254, 256 have not been charged.

If the controller circuitry 165, 232 determines that this is a first switching cycle (e.g., Block 710 returns a result of YES), the charging circuitry 150, 226 of FIGS. 1, 2, 3, and 4 charges first capacitors. (Block 720). In some examples, during the first switching cycle, the controller circuitry 165, 232 of FIGS. 1 and 2 closes the switch 244 of FIGS. 2, 3, and 4 to charge the set of first capacitors 250, 254. Also, during the first switching cycle, the controller circuitry 165, 232 opens the switch 248 of FIGS. 2, 3, and 4 to keep the set of second capacitors 252, 256 discharged. In such examples, the charging circuitry 226 may be referred to as being structured to charge the set of first capacitors 250, 254 and the charging circuitry 226 may be referred to as being structured not to charge the set of second capacitors 252, 256. Control proceeds to return to Block 610.

If the controller circuitry 165, 232 determines that this is not a first switching cycle (e.g., Block 710 returns a result of NO), the controller circuitry 165, 232 determines if the switching cycle is an even switching cycle. (Block 730). In some examples, the controller circuitry 165, 232 generates a first and second switching signals to control the switches 244, 248, 258, 260, 262, 264 of FIGS. 2, 3, and 4. In such examples, the flip-flop 270 of FIG. 2 generates the first switching signal by dividing the frequency of the low-side control signal and the inverter 272 of FIG. 2 generates the second switching signal by inverting the first switching signal. The controller circuitry 165, 232 uses the first switching signal to control the switch 244, which is structured to charge the set of first capacitors 250, 254 when closed. In example operation, the flip-flop 270 switches the states of the first and second switching signals after each pulse of the low-side control signal. For example, during even pulses (e.g., every other pulse), the first switching signal is in a first state and the second switching signal is in a second state. In such examples, during odd pulses (e.g., every other pulse), the first switching signal is in the second state and the second switching signal is in the first state.

If the controller circuitry 165, 232 determines that the switching cycle is an even switching cycle (e.g., Block 730 returns a result of YES), the charging circuitry 150, 220 charges second capacitors to generate a switching voltage. (Block 740). In some examples, the controller circuitry 165, 232 causes the charging circuitry 150, 226 to charge the set of second capacitors 252, 256 responsive to the second switching signal closing the switch 248. In such an example, the transistor 246 of FIGS. 2, 3, and 4 charges the set of second capacitors 252, 256 using a current that is proportional to the current through the transistor 234 of FIGS. 2, 3, and 4. In example operations, the second switching signal closes the switches 260, 264 to set the switching voltage as the voltage between the capacitor 250 and the switch 244. For example, during the operations of Block 740, the controller circuitry 165, 232 structures the gate driver circuitry 210 to the first configuration that is illustrated in FIG. 3.

The charging circuitry 150, 226 determines a reference voltage using the first capacitors. (Block 750). In some examples, the controller circuitry 165, 232 disconnects the charging circuitry 150, 226 from the set of first capacitors 250, 254 responsive to the first switching signal opening the switch 244. In such an example, the switch 244 prevents the transistor 242 of FIGS. 2, 3, and 4 from charging the set of first capacitors 250, 254. In example operation, the first switching signal opens the switches 258, 262 to set the reference voltage as a voltage between the capacitors 252, 256. For example, during the operations of Block 750, the controller circuitry 165, 232 structures the gate driver circuitry 210 to the first configuration that is illustrated in FIG. 3. Control proceeds to Block 780.

Although in the example of FIG. 7 operations of Block 740 occur before operations of Block 750, the operations of Blocks 740, 750 may occur at approximately the same time. For example, the charging circuitry 150, 226 discharges the first capacitors and charges the second capacitors of the capacitor circuitry 155, 228 at approximately the same time.

If the controller circuitry 165, 232 the switching cycle is not an even switching cycle (e.g., Block 730 returns a result of NO), the charging circuitry 150, 220 charges the first capacitors to generate the switching voltage. (Block 760). In some examples, the controller circuitry 165, 232 causes the charging circuitry 150, 226 to charge the set of first capacitors 250, 254 responsive to the first switching signal closing the switch 244. In such an example, the transistor 242 charges the set of first capacitors 250, 254 using a current that is proportional to the current through the transistor 234. In example operation, the first switching signal also closes the switches 258, 262 to set the switching voltage as the voltage between the capacitor 252 and the switch 248. For example, during the operations of Block 760, the controller circuitry 165, 232 structures the gate driver circuitry 210 to the second configuration that is illustrated in FIG. 4.

The charging circuitry 150, 226 determines the reference voltage using the first capacitors. (Block 770). In some examples, the controller circuitry 165, 232 disconnects the charging circuitry 150, 226 from the set of second capacitors 252, 256 responsive to the second switching signal opening the switch 248. In such an example, the switch 248 prevents the transistor 246 from charging the set of second capacitors 252, 256. In example operation, the second switching signal opens the switches 260, 264 to set the reference voltage as a voltage between the capacitors 250, 254. For example, during the operations of Block 770, the controller circuitry 165, 232 structures the gate driver circuitry 210 to the second configuration that is illustrated in FIG. 4. Control proceeds to Block 780.

Although in the example of FIG. 7 operations of Block 760 occur before operations of Block 770, the operations of Blocks 760, 770 may occur at approximately the same time. For example, the charging circuitry 150, 220 charges the first capacitors and discharges the second capacitors of the capacitor circuitry 155, 228 at approximately, preferably exactly, the same time.

The comparator circuitry 170, 233 determines if the switching voltage is greater than the reference voltage. (Block 780). In some examples, the multiplexer circuitry 160, 230 of FIGS. 1 and 2 supply the reference voltage and the switching voltage to the comparator circuitry 170, 233. In such examples, the comparator circuitry 170, 233 compares the switching voltage and the reference voltage to control the current source circuitry 135, 220.

If comparator circuitry 170, 233 determines that the switching voltage is not greater than the reference voltage (e.g., Block 780 returns a result of NO), control proceeds to return to Block 780. In some examples, the comparator circuitry 170, 233 keeps the current source circuitry 135, 220 enabled (e.g., supplying current) until the switching voltage is greater than the reference voltage. In such example operations, an output of the comparator circuitry 170, 233 changes once the switching voltage is greater than or equal to the reference voltage.

If comparator circuitry 170, 233 determines that the switching voltage is greater than the reference voltage (e.g., Block 780 returns a result of YES), the comparator circuitry 170, 233 reduces the gate driver current. (Block 790). In some examples, the comparator circuitry 170, 233 disables the current source circuitry 135, 220 responsive to a determination that the switching voltage is greater than the reference voltage. Advantageously, the comparator circuitry 170, 233 decreases the gate driver current by disabling the current source circuitry 135, 220. Advantageously, the comparator circuitry 170, 233 decreases the slew rate of the transistor 216 by decreasing the gate driver current. Advantageously, during a first duration of time, the transistor 216 has a relatively high slew rate, which has a relatively high-power efficiency, and during a second duration of time, the transistor 216 has a lower slew rate, which prevents excessive stress on the motor 110. Advantageously, the gate driver circuitry 125, 210 increases power efficiency by using multiple slew rates to control the transistor 216.

Although example methods are described with reference to the flowchart illustrated in FIG. 7, many other methods of implementing the gate driver circuitry 125, 210 of FIGS. 1, 2, 3, 4, and 5 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

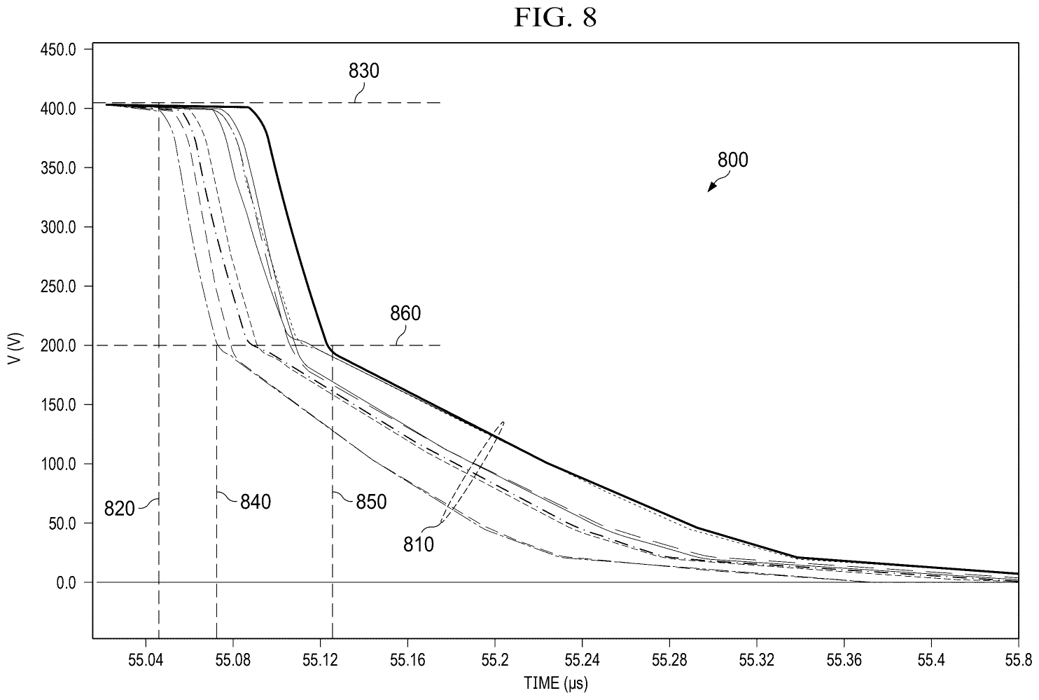

FIG. 8 is a timing diagram 800 of an example switching operation of the gate driver circuitry 125, 210 of FIGS. 1, 2, 3, and 4. In the example of FIG. 8, the timing diagram 800 illustrates example drain voltages 810. The drain voltages 810 represent voltages across the transistor 216 of FIGS. 2, 3, and 4 across switching events. During the switching event of FIG. 8, the gate driver circuitry 125, 210 turns on the transistor 216, which couples the motor 110 of FIG. 1 or the load 204 of FIGS. 2, 3, and 4 to the common terminal. At a first time 820, external circuitry supplies a low-side control signal to the gate driver circuitry 125, 210 to turn on the transistor 216. At the first time 820, the voltage at the drain of the transistor 216 is a first voltage 830, which is approximately four-hundred volts (V). In the example of FIG. 8, the first voltage 830 represents the first supply voltage, which is provided at the first supply terminal.

Between the first time 820 and a second time 840, the current source circuitry 130, 135, 218, 220 of FIGS. 1, 2, 3, and 4 both supply current to generate the gate drive current. Between the first time 820 and the second time 840, the gate drive current has a first magnitude and sets the slew rate of the transistor 216 to a relatively high value. Advantageously, between the first time 820 and the second time 840, the transistor 216 has a relatively high-power efficiency responsive to the relatively high slew rate.

Between the second time 840 and a third time 850, the drain voltages 810 are approximately equal to a second voltage 860, which is approximately two-hundred volts. The second voltage 860 is a voltage approximately equal to one-half of the first voltage 830. Between the second time 840 and the third time 850, the comparator circuitry 170, 233 of FIGS. 1, 2, 3, and 4 determines that the switching voltage is greater than the reference voltage and disables the current source circuitry 135, 220. Between the second time 840 and the third time 850, the comparator circuitry 170, 233 decreases the gate drive current and the slew rate by disabling the current source circuitry 135, 220. Advantageously, decreasing the slew rate of the transistor 216 decreases the amount of stress applied to the motor 110 or the load 204 during switching operations. Advantageously, the gate driver circuitry 125, 210 increases the power efficiency of switching operations by having the relatively high slew rate for at least a portion of the switching operations of FIG. 8.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description.

Modifications are possible in the described embodiments, and other embodiments are possible, within the scope of the claims.

What is claimed is:

1. An apparatus comprising:
current source circuitry having a control terminal;
charging circuitry having a first terminal and a second terminal;
capacitor circuitry having a first terminal, a second terminal, a third terminal, and a fourth terminal, the first terminal of the capacitor circuitry coupled to the second terminal of the charging circuitry, the second terminal of the capacitor circuitry coupled to the third terminal of the charging circuitry; and
comparator circuitry having a first terminal, a second terminal, and an output terminal, the first terminal of the comparator circuitry coupled to the third terminal of the capacitor circuitry, the second terminal of the comparator circuitry coupled to the fourth terminal of the capacitor circuitry, the output terminal of the comparator circuitry coupled to the control terminal of the current source circuitry.

2. The apparatus of claim 1, wherein the charging circuitry includes:
a first transistor having a first terminal and a control terminal;
a first switch having a first terminal and a second terminal, the first terminal of the first switch is coupled to the first terminal of the first transistor, the second terminal of the first switch coupled to the first terminal of the capacitor circuitry;
a second transistor having a first terminal and a control terminal, the control terminal of the second transistor is coupled to the control terminal of the first transistor; and
a second switch having a first terminal and a second terminal, the first terminal of the second switch is coupled to the first terminal of the second transistor, the second terminal of the second switch is coupled to the second terminal of the capacitor circuitry.

3. The apparatus of claim 1, wherein the capacitor circuitry includes:
a first capacitor having a first terminal and a second terminal, the first terminal of the first capacitor coupled to the first terminal of the charging circuitry;
a second capacitor having a terminal coupled to the first terminal of the comparator circuitry and the second terminal of the first capacitor; and
a third capacitor having a terminal coupled to the second terminal of the charging circuitry and the second terminal of the comparator circuitry.

4. The apparatus of claim 1, wherein the capacitor circuitry includes:
a first capacitor having a terminal coupled to the second terminal of the charging circuitry and the first terminal of the comparator circuitry;
a second capacitor having a first terminal and a second terminal, the first terminal of the second capacitor coupled to the third terminal of the charging circuitry; and
a third capacitor having a terminal coupled to the second terminal of the comparator circuitry and the second terminal of the second capacitor.

5. The apparatus of claim 1, wherein the capacitor circuitry further has a fifth terminal and a sixth terminal, the apparatus further comprising multiplexer circuitry having a first terminal, a second terminal, a third terminal, a fourth terminal, a fifth terminal, and a sixth terminal, the first terminal of the multiplexer circuitry is coupled to the third terminal of the capacitor circuitry, the second terminal of the multiplexer circuitry is coupled to the fourth terminal of the capacitor circuitry, the third terminal of the multiplexer circuitry is coupled to the fifth terminal of the capacitor circuitry, the fourth terminal of the multiplexer circuitry is coupled to the sixth terminal of the capacitor circuitry, the fifth terminal of the multiplexer circuitry is coupled to the first terminal of the comparator circuitry, the sixth terminal of the multiplexer circuitry is coupled to the second terminal of the comparator circuitry.

6. The apparatus of claim 1, wherein the current source circuitry further has an output terminal, the charging circuitry further has a third terminal, the apparatus further comprising:
a capacitor having a first terminal and a second terminal, the first terminal of the capacitor is coupled to the third terminal of the charging circuitry; and
a transistor having a first terminal and a control terminal, the first terminal of the transistor coupled to the second terminal of the capacitor, the control terminal of the transistor coupled to the output terminal of the current source circuitry.

7. The apparatus of claim 6, further comprising current multiplication circuitry having a first terminal and a second terminal, the first terminal of the current multiplication circuitry coupled to the first terminal of the capacitor and the third terminal of the charging circuitry, the second terminal of the current multiplication circuitry coupled to the output terminal of the current source circuitry, and the control terminal of the transistor.

8. The apparatus of claim 1, wherein the current source circuitry is first current source circuitry, the first current source circuitry further has an output terminal, the apparatus further comprising second current source circuitry having an output terminal coupled to the output terminal of the first current source circuitry.

9. An apparatus comprising:
capacitor circuitry including:
a set of first capacitors; and
a set of second capacitors;
charging circuitry coupled to the capacitor circuitry, the charging circuitry configured to:
determine a reference voltage using the set of first capacitors; and
generate a switching voltage by charging the set of second capacitors; and
comparator circuitry coupled to the capacitor circuitry, the comparator circuitry configured to decrease a drive current responsive to a comparison of the reference voltage to the switching voltage.

10. The apparatus of claim 9, further comprising controller circuitry coupled to the charging circuitry, the controller circuitry configured to:
generate a first control signal by dividing a pulse width modulation (PWM) signal;
generate a second control signal by inverting the first control signal;
cause the charging circuitry to generate the reference voltage responsive to the first control signal; and
cause the charging circuitry to generate the switching voltage responsive to the second control signal.

11. The apparatus of claim 9, wherein the charging circuitry is further configured to:
generate the switching voltage by charging the set of first capacitors; and
determine the reference voltage using the set of second capacitors.

12. The apparatus of claim 11, further comprising multiplexer circuitry coupled between the capacitor circuitry and the comparator circuitry, the multiplexer circuitry configured to:
supply the switching voltage from one of the set of first capacitors or the set of second capacitors to the comparator circuitry; and
supply the reference voltage from one of the set of first capacitors or the set of second capacitors to the comparator circuitry.

13. The apparatus of claim 9, further comprising current source circuitry coupled to the comparator circuitry, the current source circuitry configured to supply the drive current based on the comparison of the reference voltage to the switching voltage.

14. The apparatus of claim 13, wherein the current source circuitry is first current source circuitry, the apparatus further comprising second current source circuitry coupled to the first current source circuitry, the second current source circuitry configured to increase the drive current.

15. The apparatus of claim 13, further comprising a transistor coupled to the current source circuitry, the transistor configured to:
decrease a voltage of the transistor at a first slew rate responsive to a first current from the current source circuitry; and
decrease the voltage of the transistor at a second slew rate responsive to a second current from the current source circuitry, the second current is less than the first current.

16. An apparatus comprising:
a transistor having a control terminal; and
current source circuitry having a first terminal and a control terminal, the first terminal of the current source circuitry coupled to the control terminal of the transistor;
comparator circuitry having a first terminal, a second terminal, and an output terminal, the output terminal of the comparator circuitry coupled to the control terminal of the current source circuitry; and
capacitor circuitry having a first terminal and a second terminal, the first terminal of the capacitor circuitry coupled to the first terminal of the comparator circuitry, the second terminal of the capacitor circuitry coupled to the second terminal of the comparator circuitry.

17. The apparatus of claim 16, wherein the capacitor circuitry further has a third and fourth terminal, the apparatus further comprising charging circuitry having a first terminal and a second terminal, the first terminal of the charging circuitry is coupled to the third terminal of the capacitor circuitry, and the second terminal of the charging circuitry is coupled to the fourth terminal of the capacitor circuitry.

18. The apparatus of claim 17, wherein the transistor is a first transistor, the charging circuitry includes:
a second transistor having a first terminal and a control terminal;
a first switch having a first terminal and a second terminal, the first terminal of the first switch is coupled to the first terminal of the second transistor, the second terminal of the first switch coupled to the third terminal of the capacitor circuitry;
a third transistor having a first terminal and a control terminal, the control terminal of the third transistor is coupled to the control terminal of the second transistor; and
a second switch having a first terminal and a second terminal, the first terminal of the second switch is coupled to the first terminal of the third transistor, the second terminal of the second switch is coupled to the fourth terminal of the capacitor circuitry.

19. The apparatus of claim 16, wherein the capacitor circuitry includes:
a first capacitor having a terminal;
a second capacitor having a terminal coupled to the first terminal of the comparator circuitry and the second terminal of the first capacitor; and
a third capacitor having a terminal coupled to the second terminal of the comparator circuitry.

20. The apparatus of claim 16, wherein the capacitor circuitry further has a third terminal and a fourth terminal, the apparatus further comprising multiplexer circuitry having a first terminal, a second terminal, a third terminal, a fourth terminal, a fifth terminal, and a sixth terminal, the first terminal of the multiplexer circuitry is coupled to the first terminal of the capacitor circuitry, the second terminal of the multiplexer circuitry is coupled to the second terminal of the capacitor circuitry, the third terminal of the multiplexer circuitry is coupled to the third terminal of the capacitor circuitry, the fourth terminal of the multiplexer circuitry is coupled to the fourth terminal of the capacitor circuitry, the fifth terminal of the multiplexer circuitry is coupled to the first terminal of the comparator circuitry, the sixth terminal of the multiplexer circuitry is coupled to the second terminal of the comparator circuitry.
